(19) United States
(12) Patent Application Publication
(10) Pub. No.: US 2024/0260179 A1
(43) Pub. Date: Aug. 1, 2024

(54) PRINTED WIRING BOARD

(71) Applicant: IBIDEN CO., LTD., Ogaki (JP)

(72) Inventors: Jun SAKAI, Ogaki (JP); Shiho SHIMADA, Ogaki (JP)

(73) Assignee: IBIDEN CO., LTD., Ogaki (JP)

(21) Appl. No.: 18/426,547

(22) Filed: Jan. 30, 2024

(30) Foreign Application Priority Data
Jan. 30, 2023 (JP) 2023-012259

(51) Int. Cl. H05K 1/02; H05K 1/05; H05K 3/16

(52) U.S. Cl. CPC H05K 1/0298; H05K 1/053; H05K 3/16; H05K 2201/0209; H05K 2201/0338; H05K 2203/0723

(57) ABSTRACT

A printed wiring board includes a conductor layer, an outermost insulating layer formed on the conductor layer and having an opening exposing a portion of the conductor layer, and a metal post formed in the opening of the outermost insulating layer and including a seed layer and an electrolytic plating layer formed on the seed layer such that the metal post has a height exceeding a surface of the outermost insulating layer and has a portion exceeding a height of the outermost insulating layer, the seed layer of the metal post has a first layer and a second layer formed on the first layer. The portion exceeding the height of the outermost insulating layer is formed such that a width of the first layer is larger than a width of the second layer, and a width of the electrolytic plating layer is larger than the width of the first layer.

### CROSS-REFERENCE TO RELATED APPLICATIONS

The present application is based upon and claims the benefit of priority to Japanese Patent Application No. 2023-012259, filed Jan. 30, 2023, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2019-125709 describes a metal post that includes a seed layer and a metal plating layer and has a portion exceeding a height of an outermost insulating layer. The entire contents of this publication are incorporated herein by reference.

### SUMMARY OF THE INVENTION

According to one aspect of the present invention, a printed wiring board includes a conductor layer, an outermost insulating layer formed on the conductor layer such that the outermost insulating layer has an opening exposing a portion of the conductor layer, and a metal post formed in the opening of the outermost insulating layer and including a seed layer and an electrolytic plating layer formed on the seed layer such that the metal post has a height exceeding a surface of the outermost insulating layer and has a portion exceeding a height of the outermost insulating layer. The seed layer of the metal post has a first layer and a second layer formed on the first layer such that the metal post includes the first layer, the second layer, and the electrolytic plating layer, and the portion of the metal post exceeding the height of the outermost insulating layer is formed such that a width of the first layer is larger than a width of the second layer, and a width of the electrolytic plating layer is larger than the width of the first layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2 is an enlarged cross-sectional view schematically illustrating a portion of a printed wiring board according to an embodiment of the present invention;

FIG. 3 is a cross-sectional view schematically illustrating a state in which an external component is connected to a printed wiring board according to an embodiment of the present invention;

FIG. 4A is a cross-sectional view schematically illustrating a method for manufacturing a printed wiring board according to an embodiment of the present invention;

FIG. 4B is a cross-sectional view schematically illustrating a method for manufacturing a printed wiring board according to an embodiment of the present invention;

FIG. 4C is a cross-sectional view schematically illustrating a method for manufacturing a printed wiring board according to an embodiment of the present invention;

FIG. 4D is a cross-sectional view schematically illustrating a method for manufacturing a printed wiring board according to an embodiment of the present invention;

FIG. 4E is a cross-sectional view schematically illustrating a method for manufacturing a printed wiring board according to an embodiment of the present invention;

FIG. 4F is a cross-sectional view schematically illustrating a method for manufacturing a printed wiring board according to an embodiment of the present invention; and

FIG. 4G is a cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### EMBODIMENT

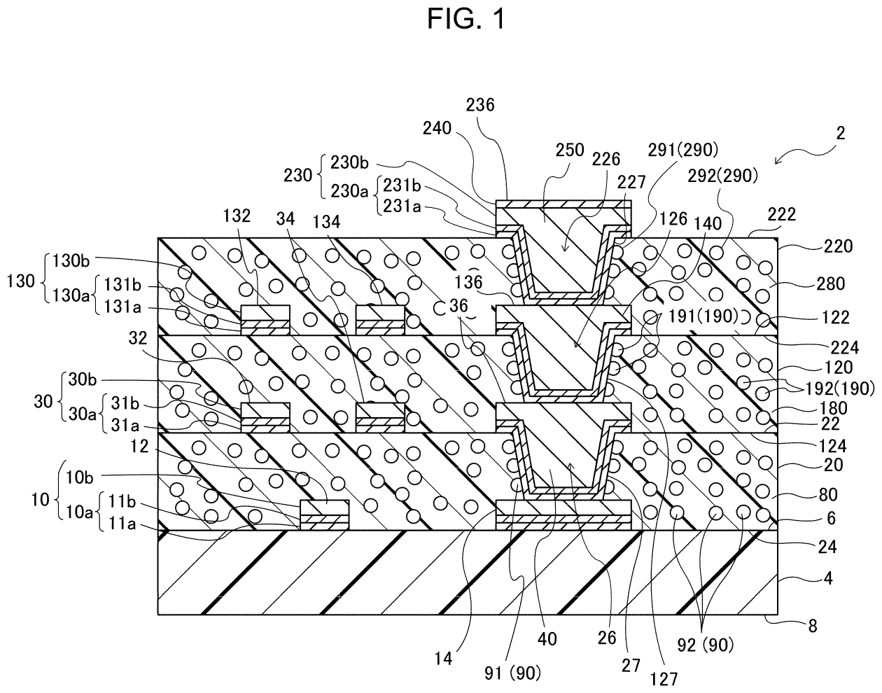

FIG. 1 is a cross-sectional view illustrating a printed wiring board 2 of an embodiment. As illustrated in FIG. 1, the printed wiring board 2 includes an insulating layer 4, a first conductor layer 10, a first resin insulating layer 20, a second conductor layer 30, a first via conductor 40, a second resin insulating layer 120, a third conductor layer 130, a second via conductor 140, an outermost insulating layer 220, and a metal post 250.

The insulating layer 4 is formed using a resin. The insulating layer 4 may contain inorganic particles such as silica particles. The insulating layer 4 may contain a reinforcing material such as a glass cloth. The insulating layer 4 has a third surface 6 (upper surface in the drawing) and a fourth surface 8 (lower surface in the drawing) on the opposite side with respect to the third surface 6.

The first conductor layer 10 is formed on the third surface 6 of the insulating layer 4. The first conductor layer 10 includes a signal wiring 12 and a pad 14. Although not illustrated in the drawing, the first conductor layer 10 also includes conductor circuits other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). The seed layer (10a) is formed of a first layer (11a) on the third surface 6 and a second layer (11b) on the first layer (11a). The first layer (11a) is formed of a copper alloy containing copper, silicon and aluminum. The second layer (11b) is formed of copper. The electrolytic plating layer (10b) is formed of copper. The first layer (11a) is in contact with the insulating layer 4.

The first resin insulating layer 20 is formed on the third surface 6 of the insulating layer 4 and on the first conductor layer 10. The first resin insulating layer 20 has a fifth surface 22 (upper surface in the drawing) and a sixth surface 24 (lower surface in the drawing) on the opposite side with respect to the fifth surface 22. The sixth surface 24 of the first resin insulating layer 20 faces the first conductor layer 10. The first resin insulating layer 20 has an opening 26 that exposes the pad 14. The first resin insulating layer 20 is formed of a resin 80 and a large number of inorganic particles 90 dispersed in the resin 80. The resin 80 is an epoxy resin. Examples of the resin 80 include a thermosetting resin and a photocurable resin. Examples of the inorganic particles 90 include silica particles and alumina particles. The inorganic particles 90 have an average particle size of 0.5 μm and particle sizes in a range of 0.1 μm or more and 5.0 μm or less.

As illustrated in FIG. 1, the inorganic particles 90 include first inorganic particles 91 forming an inner wall surface 27 of the opening 26 and second inorganic particles 92 embedded in the resin 80. The second inorganic particles 92 each have a spherical shape. The first inorganic particles 91 each have a shape obtained by cutting a sphere along a flat surface. The first inorganic particles 91 each have a shape obtained by cutting a second inorganic particle 92 along a flat surface. The first inorganic particles 91 and the second inorganic particles 92 are different in shape.

As illustrated in FIG. 1, the fifth surface 22 of the first resin insulating layer 20 is mostly formed of the resin 80. A small amount of the inorganic particles 90 (second inorganic particles 92) are exposed from the fifth surface 22. No unevenness is formed on the fifth surface 22 of the first resin insulating layer 20. The fifth surface 22 is not roughened. The fifth surface 22 is formed smooth. The fifth surface 22 has an arithmetic mean roughness (Ra) of 0.02 μm or more and 0.06 μm or less.

The inner wall surface 27 of the opening 26 is formed of the resin 80 and the first inorganic particles 91. The first inorganic particles 91 each have a flat part. The inner wall surface 27 is formed of the resin 80 and the flat parts of the first inorganic particles 91. The inner wall surface 27 is formed smooth.

The second conductor layer 30 is formed on the fifth surface 22 of the first resin insulating layer 20. The second conductor layer 30 includes a first signal wiring 32, a second signal wiring 34, and a land 36. Although not illustrated in the drawing, the second conductor layer 30 also includes conductor circuits other than the first signal wiring 32, the second signal wiring 34, and the land 36. The first signal wiring 32 and the second signal wiring 34 form a pair wiring. The second conductor layer 30 is mainly formed of copper. The second conductor layer 30 is formed of a seed layer (30a) on the fifth surface 22 and an electrolytic plating layer (30b) on the seed layer (30a). The seed layer (30a) is formed by a first layer (31a) on the fifth surface 22 and a second layer (31b) on the first layer (31a). The first layer (31a) is formed of a copper alloy containing copper, silicon and aluminum. The second layer (31b) is formed of copper. The electrolytic plating layer (30b) is formed of copper. The first layer (31a) is in contact with the fifth surface 22. The second layer (31b) adheres to the electrolytic plating layer (30b). A surface of the second conductor layer 30 facing the fifth surface 22 of the first resin insulating layer 20 is formed along a surface shape of the fifth surface 22. The second conductor layer 30 does not enter an inner side of the fifth surface 22 of the first resin insulating layer 20.

The first via conductor 40 is formed in the opening 26. The first via conductor 40 connects the first conductor layer 10 and the second conductor layer 30. In FIG. 1, the first via conductor 40 connects the pad 14 and the land 36. The first via conductor 40 is formed of a seed layer (30a) and an electrolytic plating layer (30b) on the seed layer (30a). The seed layer (30a) that forms the first via conductor 40 and the seed layer (30a) that forms the second conductor layer 30 are common. The first layer (31a) is in contact with the inner wall surface 27.

The second resin insulating layer 120 is formed on the fifth surface 22 of the first resin insulating layer 20 and on the second conductor layer 30. The second resin insulating layer 120 has a seventh surface 122 (upper surface in the drawing) and an eighth surface 124 (lower surface in the drawing) on the opposite side with respect to the seventh surface 122. The eighth surface 124 of the second resin insulating layer 120 faces the second conductor layer 30. The second resin insulating layer 120 has an opening 126 that exposes the land 36. The second resin insulating layer 120 is formed of a resin 180 and a large number of inorganic particles 190 dispersed in the resin 180. The resin 180 and the inorganic particles 190 are respectively similar to the resin 80 and the inorganic particles 90 of the first resin insulating layer 20. The inorganic particles 190 include first inorganic particles 191 forming an inner wall surface 127 of the opening 126 and second inorganic particles 192 embedded in the resin 180. The second inorganic particles 192 each have a spherical shape. The first inorganic particles 191 each have a shape obtained by cutting a sphere with a plane.

The seventh surface 122 of the second resin insulating layer 120 is formed mostly of the resin 180. A small amount of the inorganic particles 190 (second inorganic particles 192) are exposed from the seventh surface 122. No unevenness is formed on the seventh surface 122 of the second resin insulating layer 120. The seventh surface 122 is not roughened. The seventh surface 122 is formed smooth.

The inner wall surface 127 of the opening 126 is formed of the resin 180 and the first inorganic particles 191. The inner wall surface 127 is formed of the resin 180 and flat parts of the first inorganic particles 191. The inner wall surface 127 is formed smooth.

The third conductor layer 130 is formed on the seventh surface 122 of the second resin insulating layer 120. The third conductor layer 130 includes a first signal wiring 132, a second signal wiring 134, and a land 136. Although not illustrated in the drawing, the third conductor layer 130 also includes conductor circuits other than the first signal wiring 132, the second signal wiring 134, and the land 136. The first signal wiring 132 and the second signal wiring 134 form a pair wiring. The third conductor layer 130 is mainly formed of copper. The third conductor layer 130 is formed of a seed layer (130a) on the seventh surface 122 and an electrolytic plating layer (130b) on the seed layer (130a). The seed layer (130a) and the electrolytic plating layer (130b) are respectively similar to the seed layer (30a) and the electrolytic plating layer (30b) of the second conductor layer 30. The seed layer (130a) is formed of a first layer (131a) on the seventh surface 122 and a second layer (131b) on the first layer (131a). The first layer (131a) is formed of a copper alloy containing copper, silicon and aluminum. The second layer (131b) is formed of copper. The electrolytic plating layer (130b) is formed of copper. The first layer (131a) is in contact with the seventh surface 122. A surface of the third conductor layer 130 facing the seventh surface 122 of the second resin insulating layer 120 is formed along a surface shape of the seventh surface 122. The third conductor layer 130 does not enter an inner side of the seventh surface 122 of the second resin insulating layer 120.

The second via conductor 140 is formed in the opening 126. The second via conductor 140 connects the second conductor layer 30 and the third conductor layer 130. In FIG. 1, the second via conductor 140 connects the land 36 and the land 136. The second via conductor 140 is formed of a seed layer (130a) and an electrolytic plating layer (130b) on the seed layer (130a). The seed layer (130a) that forms the second via conductor 140 and the seed layer (130a) that forms the third conductor layer 130 are common. The first layer (131a) is in contact with the inner wall surface 127.

The outermost insulating layer 220 is formed on the seventh surface 122 of the second resin insulating layer 120 and on the third conductor layer 130. The outermost insulating layer 220 has a first surface 222 (upper surface in the drawing) and a second surface 224 (lower surface in the drawing) on the opposite side with respect to the first surface 222. The second surface 224 of the outermost insulating layer 220 faces the third conductor layer 130. The outermost insulating layer 220 has an opening 226 that exposes the land 136 of the third conductor layer 130. The outermost insulating layer 220 is formed of a resin 280 and a large number of inorganic particles 290 dispersed in the resin 280. The resin 280 and the inorganic particles 290 are respectively similar to the resin 80 and the inorganic particles 90 of the first resin insulating layer 20. The inorganic particles 290 include first inorganic particles 291 forming an inner wall surface 227 of the opening 226 and second inorganic particles 292 embedded in the resin 280. The second inorganic particles 292 each have a spherical shape. The first inorganic particles 291 each have a shape obtained by cutting a sphere with a plane.

The first surface 222 of the outermost insulating layer 220 is formed mostly of the resin 280. A small amount of the inorganic particles 290 (second inorganic particles 292) are exposed from the first surface 222. No unevenness is formed on the first surface 222 of the outermost insulating layer 220. The first surface 222 is not roughened. The first surface 222 is formed smooth.

The inner wall surface 227 of the opening 226 is formed of the resin 280 and the first inorganic particles 291. The inner wall surface 227 is formed of the resin 280 and flat parts of the first inorganic particles 291. The inner wall surface 227 is formed smooth.

The metal post 250 is formed in the opening 226 of the outermost insulating layer 220 and on the first surface 222 of the outermost insulating layer 220. A fourth conductor layer 230 forming the metal post 250 is formed on the first surface 222 of the outermost insulating layer 220. The fourth conductor layer 230 includes a land 236, which is a conductive circuit. Although not illustrated in the drawings, the fourth conductor layer 230 also includes lands other than the land 236. The fourth conductor layer 230 is mainly formed of copper. The fourth conductor layer 230 is formed of a seed layer (230a) on the first surface 222 and an electrolytic plating layer (230b) on the seed layer (230a). The seed layer (230a) and the electrolytic plating layer (230b) are respectively similar to the seed layer (30a) and the electrolytic plating layer (30b) of the second conductor layer 30. The seed layer (230a) is formed of a first layer (231a) on the first surface 222 and a second layer (231b) on the first layer (231a). The first layer (231a) is formed of a copper alloy containing copper, silicon and aluminum. The second layer (231b) is formed of copper. The electrolytic plating layer (230b) is formed of copper. The first layer (231a) is in contact with the first surface 222. A surface of the fourth conductor layer 230 facing the first surface 222 of the outermost insulating layer 220 is formed along a surface shape of the first surface 222. The fourth conductor layer 230 does not enter an inner side of the first surface 222 of the outermost insulating layer 220.

The metal post 250 is formed in the opening 226. The metal post 250 connects the third conductor layer 130 and the fourth conductor layer 230. In FIG. 1, the metal post 250 connects the land 136 and the land 236. Further, the metal post 250 connects the land 236 and a connection terminal of an external component. The metal post 250 is formed of a seed layer (230a) and an electrolytic plating layer (230b) on the seed layer (230a). The seed layer (230a) is formed of a first layer (231a) on the first surface 222 and a second layer (231b) on the first layer (231a). The first layer (231a) is in contact with the inner wall surface 227. A connection metal layer 240 is formed on the electrolytic plating layer (230b). The connection metal layer 240 is formed of nickel and tin.

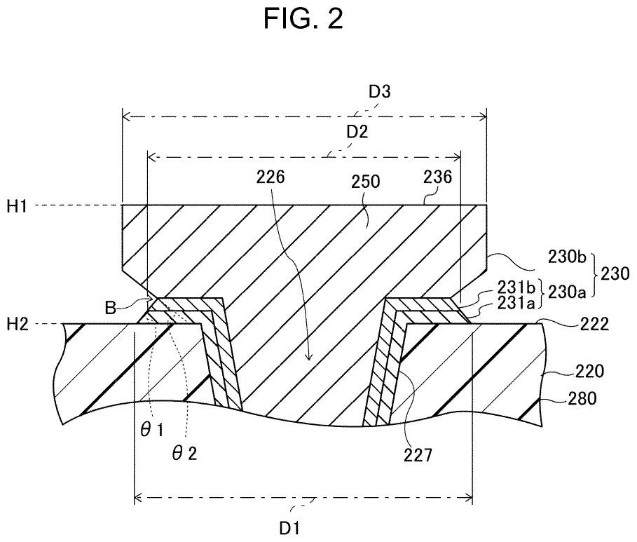

FIG. 2 is an enlarged cross-sectional view around the land 236 of the fourth conductor layer 230. As illustrated in FIG. 2, the metal post 250 is provided on the land 236. The metal post 250 is formed of the seed layer (230a) on the first surface 222 and the electrolytic plating layer (230b) on the seed layer (230a). The seed layer (230a) includes the first layer (231a) on the first surface 222 and the second layer (231b) on the first layer (231a). The first layer (231a) is in contact with the first surface 222. A surface facing the first surface 222 of the first layer (231a) is formed along a surface shape of the first surface 222. The second layer (231b) adheres to the electrolytic plating layer (230b).

As illustrated in FIG. 2, the metal post 250 is formed to have a height exceeding the first surface 222 of the outermost insulating layer 220 (a height at which a height position (H1) of an upper end of the metal post 250 is higher than a height position (H2) of the first surface 222 in an up-down direction in the drawing). In a cross section of a portion of the metal post 250 exceeding the height of the outermost insulating layer 220, a width (length in a left-right direction in the drawing) of the seed layer (230a) of the metal post 250 is smaller than a width of the electrolytic plating layer (230b). In the portion with a height exceeding the first surface 222, a width of the metal post 250 is smallest at a boundary portion (B) between the seed layer (230a) and the electrolytic plating layer (230b). A width (D1) of the first layer (231a) is larger than a width (D2) of the second layer (231b), and a width (D3) of the electrolytic plating layer (230b) is larger than the width (D1) of the first layer (231a). A first angle (θ1) between a side surface of the seed layer (230a) and the first surface 222 is larger than a second angle (θ2) between the first surface 222 and a straight line from a lower edge of a side surface of the electrolytic plating layer (230b) to the boundary portion (B) between the seed layer (230a) and the electrolytic plating layer (230b).

Although FIG. 2 illustrates the metal post 250, the conductor circuits (the signal wiring 12 and the pad 14) of the first conductor layer 10, the conductor circuits (the first signal wiring 32, the second signal wiring 34, and the land 36) of the second conductor layer 30, and the conductor circuits (the first signal wiring 132, the second signal wiring 134, and the land 136) of the third conductor layer 130 also each have a structure similar to that of the metal post 250.

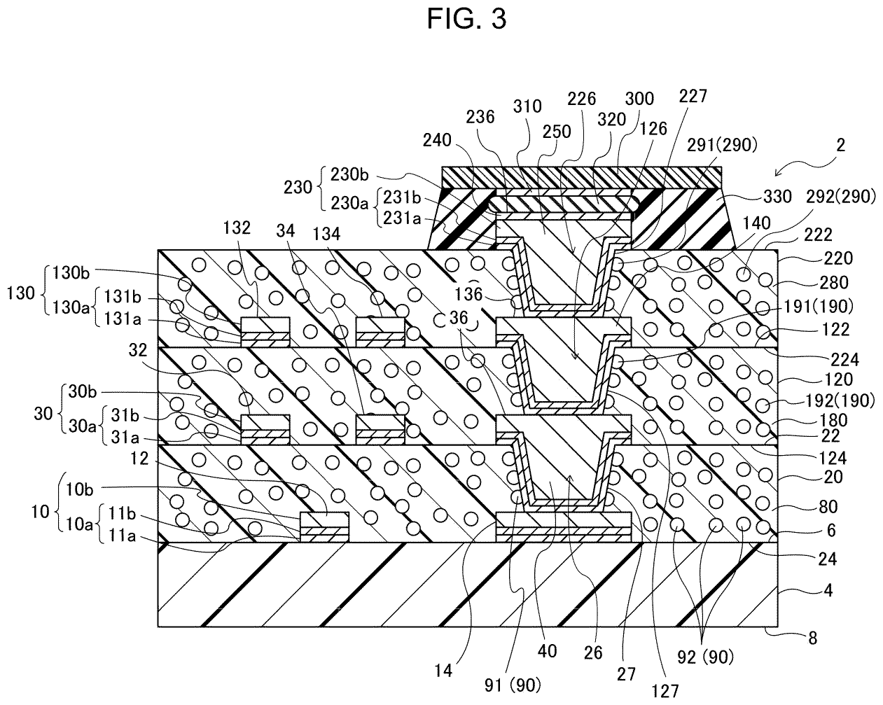

FIG. 3 is a cross-sectional view illustrating a state in which a semiconductor chip 300 is connected to the printed wiring board 2 of the embodiment. As illustrated in FIG. 3, the semiconductor chip 300, which is an external component, is connected to the printed wiring board 2. The connection metal layer 240 on the metal post 250 is connected to a connection terminal 310 of the semiconductor chip 300 via a solder 320. An underfill resin 330 is filled in a gap between the printed wiring board 2 and the semiconductor chip 300. The underfill resin 330 is an epoxy resin.

### Method for Manufacturing Printed Wiring Board

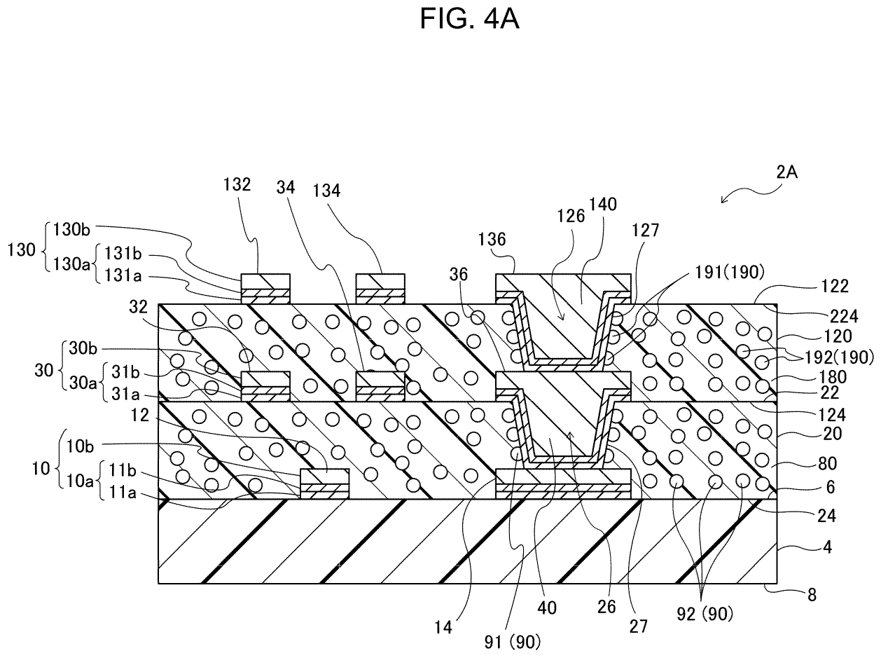

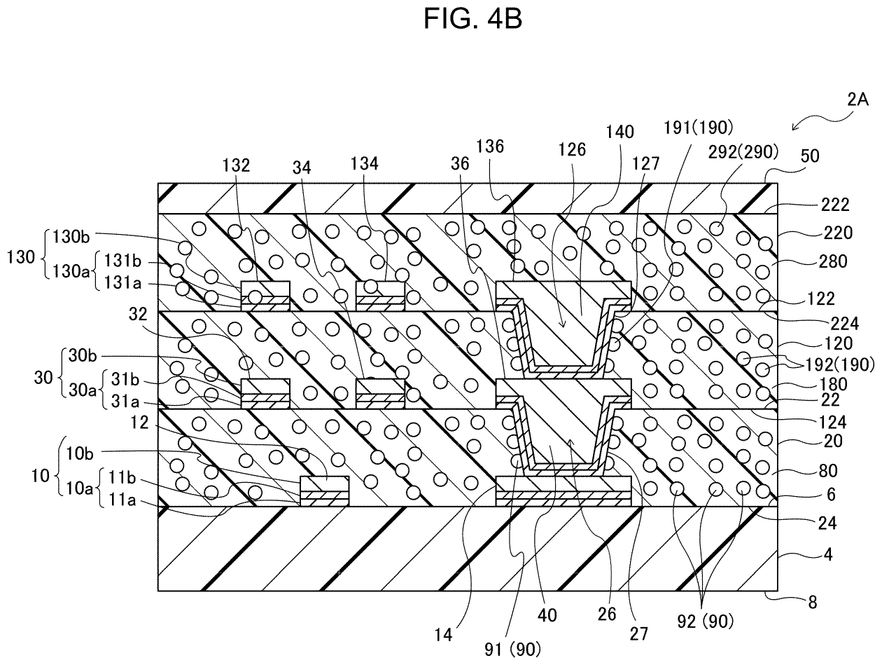

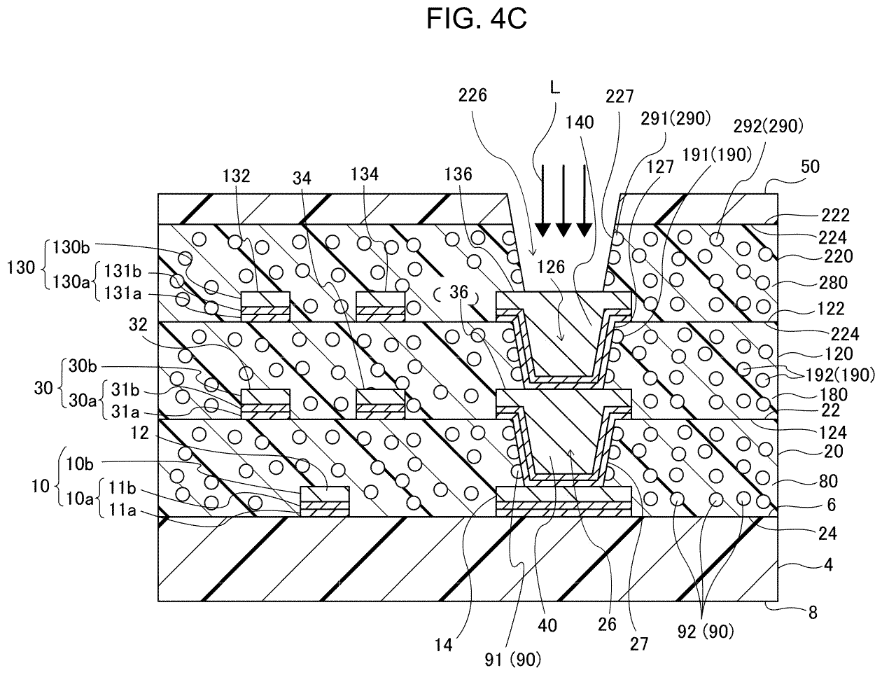

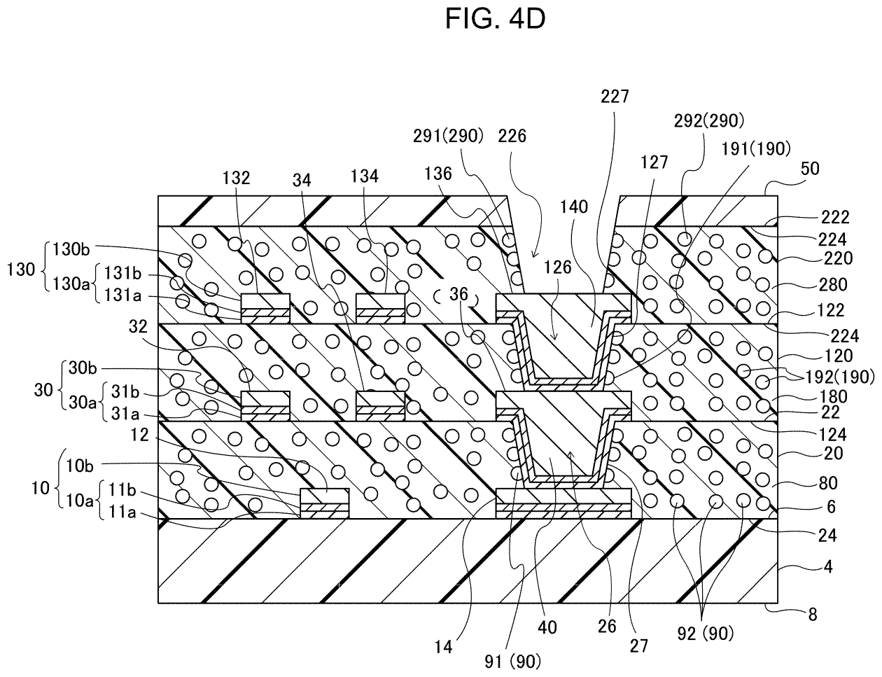

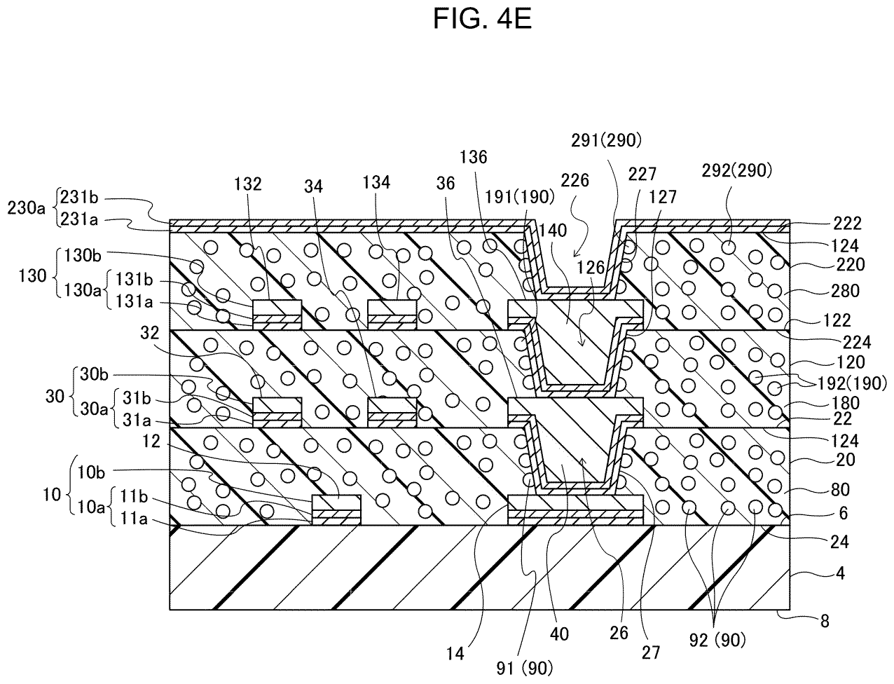

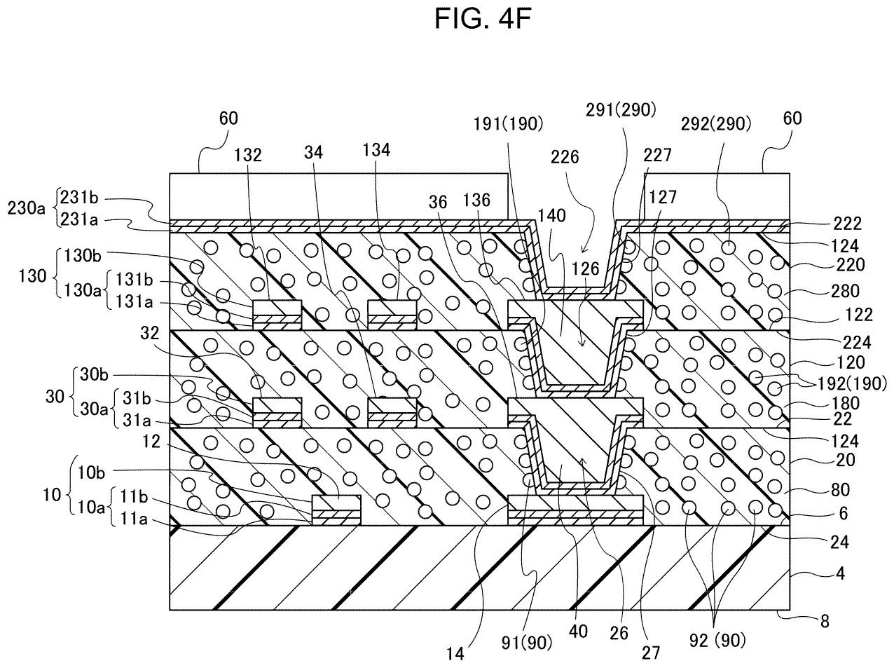

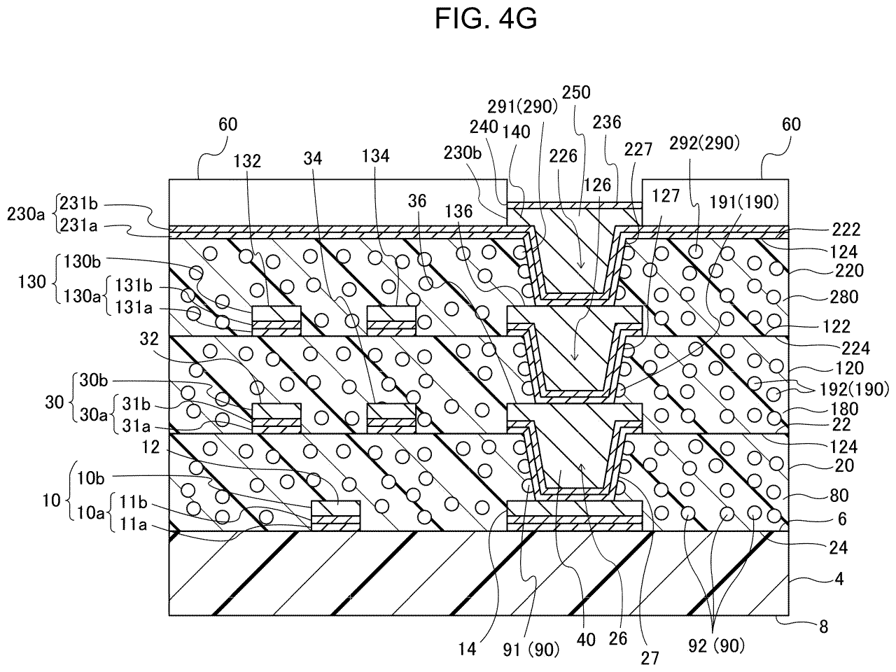

FIGS. 4A-4G illustrate a method for manufacturing the printed wiring board 2 of the embodiment. FIGS. 4A-4G are cross-sectional views.

In the method for manufacturing the printed wiring board 2 of the embodiment, as illustrated in FIG. 4A, first, a printed wiring board (2A) that is in a process of being manufactured is prepared. The printed wiring board (2A) includes the insulating layer 4, the first conductor layer 10, the first resin insulating layer 20, the second conductor layer 30, the first via conductor 40, the second resin insulating layer 120, the third conductor layer 130, and the second via conductor 140.

As illustrated in FIG. 4B, the outermost insulating layer 220 and a protective film 50 are formed on the second resin insulating layer 120 and the third conductor layer 130. The second surface 224 of the outermost insulating layer 220 faces the seventh surface 122 of the second resin insulating layer 120. The protective film 50 is formed on the first surface 222 of the outermost insulating layer 220. The outermost insulating layer 220 is formed of the resin 80. The protective film 50 completely covers the first surface 222 of the outermost insulating layer 220. An example of the protective film 50 is a film formed of polyethylene terephthalate (PET). A release agent is formed between the protective film 50 and the outermost insulating layer 220.

As illustrated in FIG. 4C, laser (L) is irradiated from above the protective film 50. The laser (L) penetrates the protective film 50 and the outermost insulating layer 220 at the same time. The opening 226 for a metal post reaching the via conductor 140 of the third conductor layer 130 is formed. The laser (L) is, for example, UV laser, or CO₂ laser. The via conductor 140 is exposed by the opening 226. When the opening 226 is formed, the first surface 222 is covered by the protective film 50. Therefore, when the opening 226 is formed, even when the resin scatters, adherence of the resin to the first surface 222 is suppressed. No unevenness is formed on the first surface 222 of the outermost insulating layer 220. The first surface 222 is not roughened. No unevenness is formed on the inner wall surface 227. The inner wall surface 227 is formed smooth.

As illustrated in FIG. 4D, the protective film 50 is removed from the outermost insulating layer 220. Roughening of the first surface 222 of the outermost insulating layer 220 is not performed. Therefore, the first surface 222 is formed smooth. The first surface 222 has an arithmetic mean roughness (Ra) of 0.02 μm or more and 0.06 μm or less.

As illustrated in FIG. 4E, the seed layer (230a) is formed on the first surface 222 of the outermost insulating layer 220. The seed layer (230a) is formed by sputtering. The formation of the seed layer (230a) is performed with a dry process. The seed layer (230a) has the first layer (231a) and the second layer (231b) formed on the first layer (231a) using a material different from that of the first layer (231a). The first layer (231a) and the second layer (231b) are formed of a combination of copper alloys of different materials, or a combination of a copper alloy and copper. The first layer (231a) is formed of a copper alloy. Adhesion strength between a copper alloy and the outermost insulating layer 220 is larger than adhesion strength between copper and the outermost insulating layer 220. The second layer (231b) is formed of a copper alloy or copper. The copper alloys of the first layer (231a) and the second layer (231b) have a copper content of 90% or more of a total weight. Since the higher the copper content is, the lower the electrical resistance can be reduced, connection reliability can be improved.

A thickness of the seed layer (230a) is in a range of 0.02 μm or more and 1 μm or less, preferably 0.03 μm or more and 0.5 μm or less, and more preferably 0.05 μm or more and 0.3 μm or less. The first surface 222 has an arithmetic mean roughness (Ra) of 0.02 μm or more and 0.06 μm or less. When the thickness of the seed layer (230a) is 0.02 μm or less, it is difficult to form the seed layer (230a) uniformly over the entire surface of the outermost insulating layer 220. Further, when the thickness is 1 μm or more, it is difficult to control a wiring width of the electrolytic plating layer (230b) during a process of removing the seed layer by etching. The first layer (231a) is formed on the first surface 222 by sputtering. A thickness of the first layer (231a) is 0.01 μm or more and 0.5 μm or less, preferably 0.02 μm or more and 0.3 μm or less, and more preferably 0.03 μm or more and 0.1 μm or less. When the thickness of the first layer (231a) is 0.01 μm or less, adhesion to the outermost insulating layer 220 decreases. When the thickness of the first layer (231a) is 0.5 μm or more, wiring resistance increases. The second layer (231b) is formed on the first layer (231a) by sputtering. A thickness of the second layer (231b) is 0.01 μm or more and 0.9 μm or less, preferably 0.02 μm or more and 0.3 μm or less, and more preferably 0.03 μm or more and 0.2 μm or less. When the thickness of the second layer (231b) is 0.01 μm or less, wiring resistance increases. When the thickness of the second layer (231b) is 0.9 μm or more, the first layer (231a) is formed thin, and thus, adhesion between a wiring and the outermost insulating layer 220 decreases.

The seed layer (230a) is formed along a surface shape of the first surface 222. The seed layer (230a) is not formed entering an inner side of the outermost insulating layer 220. An etching amount when the seed layer (230a) is removed during manufacturing can be reduced. Excessive etching of the conductor circuits can be suppressed. The widths of the conductor circuits can be made close to design values. The seed layer (230a) is also formed on the upper surface of the via conductor 140 exposed from the opening 226 and on the inner wall surface 227 of the opening 226. The first layer (231a) is formed of a copper alloy containing copper, silicon and aluminum. The second layer (231b) is formed of copper.

As illustrated in FIG. 4F, a plating resist layer 60 is formed on the seed layer (230a). The plating resist layer 60 has an opening for forming the land 236 (see FIG. 1).

As illustrated in FIG. 4G, the electrolytic plating layer (230b) is formed on the seed layer (230a) exposed from the plating resist layer 60. The electrolytic plating layer (230b) is formed of copper. The electrolytic plating layer (230b) fills the opening 226. The fourth conductor layer 230 having the land 236 is formed by the seed layer (230a) and the electrolytic plating layer (230b) on the first surface 222. The metal post 250 is formed by the seed layer (230a) and the electrolytic plating layer (230b) in the opening 226. The metal post 250 connects the via conductor 140 and the land 236. Further, the metal post 250 connects the land 236 and a connection terminal of an external component. The connection metal layer 240 is formed on the electrolytic plating layer (230b) of the metal post 250. The connection metal layer 240 is formed of nickel and tin.

As illustrated in FIG. 1, the plating resist layer 60 is removed. The seed layer (230a) exposed from the electrolytic plating layer (230b) is removed by etching. The fourth conductor layer 230 and the metal post 250 are formed at the same time. The width of the first layer (231a) is larger than the width of the second layer (231b), and the width of the electrolytic plating layer (230b) is larger than the width of the first layer (231a). An etching rate of the seed layer (230a) is higher than an etching rate of the electrolytic plating layer 2(30b). The etching rate of the seed layer is 1.1-1.5 times the etching rate of the electrolytic plating layer. The seed layer (230a) formed by sputtering has a higher ratio of an amorphous structure part to a metal crystal part compared to the electrolytic plating layer (230b). In general, the amorphous structure part has more crystal defects. The more crystal defects there are, the higher the etching rate is. An etching rate of the seed layer (230a) is higher than an etching rate of the electrolytic plating layer (230b). Therefore, an etching amount in a process of removing the seed layer (230a) during manufacturing can be reduced. Excessive etching of the conductor circuits can be suppressed. The widths of the conductor circuits can be made close to design values.

As a result of the seed layer (230a) being removed by etching, the width of the seed layer (230a) of the conductor circuit (lands 236) of the fourth conductor layer 230 becomes smaller than the width of the electrolytic plating layer (230b). In the seed layer (230a), the second layer (231b) is formed on the first layer (231a). The first layer (231a) is formed of a copper alloy. The second layer (231b) is formed of copper. By using an etching solution that allows the etching rate of the copper formed by sputtering to be larger than the etching rate of the copper alloy formed by sputtering, the width of the first layer (231a) can be made larger than the width of the second layer (231b). In the portion with a height exceeding the first surface 222, the boundary portion (B) between the second layer (231b) and the electrolytic plating layer (230b) has the smallest wiring width. Since a stress is largest at the boundary portion (B) of the wiring of the fourth conductor layer 230, the adhesion between the first layer (231a) and the outermost insulating layer 220 is improved.

In a cross section of the metal post 250, a first angle (θ1) between a side surface of the seed layer (230a) and the first surface 222 is larger than a second angle (θ2) between the first surface 222 and a straight line from a lower edge of a side surface of the electrolytic plating layer (230b) toward the boundary portion (B). Since the etching rate of the seed layer (230a) is larger than the etching rate of the electrolytic plating layer (230b), the first angle (θ1) between the side surface of the seed layer (230a) and the first surface 222 is formed larger than the second angle (θ2). As a result, a depth of the boundary portion (B) can be reduced, and thus, stress concentration can be relaxed.

In the printed wiring board 2 of the embodiment, the surface of the fourth conductor layer 230 facing the first surface 222 is formed along the surface shape of the first surface 222. Therefore, the seed layer (230a) forming the conductor circuit (lands 236) in the fourth conductor layer 230 is not formed entering an inner side of the first surface 222 of the outermost insulating layer 220. The seed layer (230a) can be reduced in thickness. Variation in the thickness of the seed layer (230a) can be reduced. An etching amount when the seed layer (230a) is removed during manufacturing can be reduced. Excessive etching of the conductor circuits can be suppressed. The widths of the conductor circuits can be made close to design values. The width (D1) of the first layer (231a) is formed larger than the width (D2) of the second layer (231b), and the width (D3) of the electrolytic plating layer (230b) is formed larger than the width (D1) of the first layer (231a). The adhesion between the seed layer (230a) and the outermost insulating layer 220 can be increased. The first surface 222 of the outermost insulating layer 220 is formed of the resin 280. No unevenness is formed on the first surface 222. An increase in standard deviation of the relative permittivity in a portion near the first surface 222 is suppressed. The relative permittivity of the first surface 222 does not significantly vary depending on location. A high quality printed wiring board 2 is provided.

### First Alternative Example

In a first alternative example of the embodiment, the first layers (11a, 31a, 131a, 231a) of the seed layers (10a, 30a, 130a, 230a) are formed of copper and a second element. The second element is selected from silicon, aluminum, titanium, nickel, chromium, carbon, oxygen, tin, calcium, magnesium, iron, molybdenum, and silver. The first layers (11a, 31a, 131a, 231a) are formed of an alloy containing copper. The second layers (11b, 31b, 131b, 231b) are formed of copper. A content (atomic weight %) of copper forming the second layers (11b, 31b, 131b, 231b) is 99.9% or more, and preferably 99.95% or more.

### Second Alternative Example

In a second alternative example of the embodiment, the first layers (11a, 31a, 131a, 231a) of the seed layers (10a, 30a, 130a, 230a) are each formed of any one metal of silicon, aluminum, titanium, nickel, chromium, carbon, oxygen, tin, calcium, magnesium, iron, molybdenum, and silver.

In the technology of Japanese Patent Application Laid-Open Publication No. 2019-125709, it may be possible that the seed layer is excessively etched, forming a recess (undercut) inwardly retracting from a lower edge of the metal plating layer on a side surface of the seed layer. As a result, a contact area between the seed layer and the outermost insulating layer on a surface of the outermost insulating layer is reduced, which may cause poor adhesion.

A printed wiring board according to an embodiment of the present invention includes: a conductor layer; an outermost insulating layer that has an opening exposing the conductor layer, a first surface, and a second surface on the opposite side with respect to the first surface and is formed on the conductor layer with the second surface facing the conductor layer; and a metal post formed in the opening. The metal post is formed of a seed layer and an electrolytic plating layer formed on the seed layer. The seed layer is formed along a surface shape of the first surface. The metal post is formed to have a height exceeding the first surface of the outermost insulating layer. The seed layer has a first layer and a second layer formed on the first layer. The metal post is formed of the first layer, the second layer, and the electrolytic plating layer in order from a side close to the outermost insulating layer. In a cross section of a portion of the metal post exceeding a height of the outermost insulating layer, a width of the first layer is larger than a width of the second layer, and a width of the electrolytic plating layer is larger than the width of the first layer.

In the printed wiring board according to an embodiment of the present disclosure, the seed layer forming the metal post is formed along the surface shape of the first surface. Therefore, the seed layer is not formed entering an inner side of the outermost insulating layer. An etching amount when the seed layer is removed during manufacturing can be reduced. Excessive etching of the metal post can be suppressed. The width of the metal post can be made close to a design value. By forming the metal post with a height exceeding the first surface of the outermost insulating layer, adhesion between the metal post and a connection terminal of an external component can be increased. By forming the width of the first layer larger than the width of the second layer, adhesion between the seed layer and the outermost insulating layer can be increased, and thus, a high quality printed wiring board is provided.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
a conductor layer;
an outermost insulating layer formed on the conductor layer such that the outermost insulating layer has an opening exposing a portion of the conductor layer; and
a metal post formed in the opening of in the outermost insulating layer and comprising a seed layer and an electrolytic plating layer formed on the seed layer such that the metal post has a height exceeding a surface of the outermost insulating layer and has a portion exceeding a height of the outermost insulating layer,
wherein the seed layer of the metal post has a first layer and a second layer formed on the first layer such that the metal post includes the first layer, the second layer, and the electrolytic plating layer, and the portion of the metal post exceeding the height of the outermost insulating layer is formed such that a width of the first layer is larger than a width of the second layer, and a width of the electrolytic plating layer is larger than the width of the first layer.

2. The printed wiring board according to claim 1, wherein the metal post is formed such that the seed layer is formed by sputtering.

3. The printed wiring board according to claim 1, wherein the seed layer of the metal post is formed such that the first layer and the second layer are a combination of copper alloys of different materials or a combination of the copper alloys and copper.

4. The printed wiring board according to claim 3, wherein the seed layer of the metal post is formed such that the copper alloys have a copper content of 90% or more of a total weight.

5. The printed wiring board according to claim 3, wherein the metal post is formed such that the first layer of the seed layer includes a copper alloy comprising at least one of silicon, aluminum, titanium, nickel, chromium, iron, molybdenum, silver, carbon, oxygen, tin, calcium and magnesium and that the second layer of the seed layer includes copper.

6. The printed wiring board according to claim 5, wherein the metal post is formed such that the first layer of the seed layer includes a copper alloy comprising aluminum and silicon.

7. The printed wiring board according to claim 1, wherein the metal post is formed such that the first layer of the seed layer includes at least one of aluminum, titanium, nickel, chromium, calcium, magnesium, iron, molybdenum and silver and that the second layer of the seed layer includes copper.

8. The printed wiring board according to claim 1, wherein the metal post is formed such that a first angle between a side surface of the seed layer and the surface of the outermost insulating layer is larger than a second angle between the surface of the outermost insulating layer and a straight line from a lower edge of a side surface of the electrolytic plating layer toward a boundary portion between the seed layer and the electrolytic plating layer.

9. The printed wiring board according to claim 2, wherein the seed layer of the metal post is formed such that the first layer and the second layer are a combination of copper alloys of different materials or a combination of the copper alloys and copper.

10. The printed wiring board according to claim 9, wherein the seed layer of the metal post is formed such that the copper alloys have a copper content of 90% or more of a total weight.

11. The printed wiring board according to claim 9, wherein the metal post is formed such that the first layer of the seed layer includes a copper alloy comprising at least one of silicon, aluminum, titanium, nickel, chromium, iron, molybdenum, silver, carbon, oxygen, tin, calcium and magnesium and that the second layer of the seed layer includes copper.

12. The printed wiring board according to claim 11, wherein the metal post is formed such that the first layer of the seed layer includes a copper alloy comprising aluminum and silicon.

13. The printed wiring board according to claim 2, wherein the metal post is formed such that the first layer of the seed layer includes at least one of aluminum, titanium, nickel, chromium, calcium, magnesium, iron, molybdenum and silver and that the second layer of the seed layer includes copper.

14. The printed wiring board according to claim 2, wherein the metal post is formed such that a first angle between a side surface of the seed layer and the surface of the outermost insulating layer is larger than a second angle between the surface of the outermost insulating layer and a straight line from a lower edge of a side surface of the electrolytic plating layer toward a boundary portion between the seed layer and the electrolytic plating layer.

15. The printed wiring board according to claim 1, wherein the seed layer of the metal post is formed such that the first layer and the second layer are a combination of copper alloys of different materials.

16. The printed wiring board according to claim 1, wherein the seed layer of the metal post is formed such that the first layer and the second layer are a combination of the copper alloys and copper.

17. The printed wiring board according to claim 2, wherein the seed layer of the metal post is formed such that the first layer and the second layer are a combination of copper alloys of different materials.

18. The printed wiring board according to claim 2, wherein the seed layer of the metal post is formed such that the first layer and the second layer are a combination of the copper alloys and copper.

19. The printed wiring board according to claim 15, wherein the seed layer of the metal post is formed such that the copper alloys have a copper content of 90% or more of a total weight.

20. The printed wiring board according to claim 17, wherein the seed layer of the metal post is formed such that the copper alloys have a copper content of 90% or more of a total weight.
